(19) United States
(12) Patent Application Publication
(10) Pub. No.: US 2004/0196076 A1
(43) Pub. Date: Oct. 7, 2004

(54) Apparatus and method for transmitting differential signal

(76) Inventor: Jae Gan Ko, Bucheon-si (KR)

Correspondence Address: CANTOR COLBURN LLP, 55 Griffin Road South, Bloomfield, CT, 06002, US

(21) Appl. No.: 10/763,864

(22) Filed: Jan. 23, 2004

(30) Foreign Application Priority Data
Apr. 7, 2003 (KR) 2003-0021530

(51) Int. Cl. H03B 1/00

(52) U.S. Cl. 327/112

(57) ABSTRACT

Disclosed herein is an apparatus and method for transmitting a differential signal through a ternary transmission line. The differential signal transmitting apparatus includes a signal transmitting unit, a signal receiving unit, and first to third transmission lines to transmit data information between the signal transmitting and receiving units. The signal receiving unit includes first to third matching units placed between the ends of the first and second transmission lines, between the ends of the second and third transmission lines, and between the ends of the first and third transmission lines, respectively. Each of the first to third matching units has an impedance matching with the impedance of each of the first to third transmission lines.

### BACKGROUND OF THE INVENTION

1. Field of the Invention

The present invention relates to an apparatus and method for transmitting data information and, more particularly, to an apparatus and method for transmitting a differential signal, in which a voltage of a specific transmission line is compared with voltages of the remaining transmission lines to recognize data information based on the results of the voltage comparison.

2. Description of the Related Art

Generally, in order to communicate information, the transmission of data information composed of a plurality of pieces of data is required. In this case, the transmission of data is performed between circuit blocks or logic devices.

Such data transmission is performed through a single transmission line in the conventional data transmission technologies. However, since the voltage swing of data decreases close to 1V to perform high-speed transmission in information communication, a problem occurs in that the reception of data cannot be precisely performed due to noise or the like. In order to solve the problem caused due to such a low drive voltage, a differential signal transmitting apparatus for transmitting data through two transmission lines has been proposed. When data is transmitted through the two transmission lines, the reduction of reliability due to Electromagnetic Interference (EMI), which occurs when a single transmission line is used, is minimized.

FIG. 1 is a view showing a conventional differential signal transmitting apparatus. As shown in FIG. 1, the conventional differential signal transmitting apparatus includes a signal transmitting unit 110, a signal receiving unit 120, and two transmission lines 130a and 130b to transmit data information from the signal transmitting unit 110 to the signal receiving unit 120. The signal receiving unit 120 receives signals generated by the signal transmitting unit 110 through ports Pa and Pb. Further, in order to prevent the distortion of signals being transmitted, a matching means 140 is placed between the ends of the two transmission lines 130a and 130b located in the signal receiving unit 120.

FIGS. 2a and 2b are enlarged views showing a part 200 of the signal receiving unit 120 of FIG. 1, in which the impedance values of the transmission lines and the matching means are modeled and expressed. In accordance with theoretical calculation, if the impedance value Z₀ of each of the transmission lines 130a and 130b is R/2, the impedance of the matching means 140 is R. In FIG. 2a, current flows to the port Pb from the port Pa. Therefore, FIG. 2a shows a state in which the voltage Va of the port Pa is higher than the voltage Vb of the port Pb, called state “SOa”. Further, in FIG. 2b, current flows to the port Pa from the port Pb. Therefore, FIG. 2b shows a state in which the voltage Vb of the port Pb is higher than the voltage Va of the port Pa, called state “SOb”. In actual application, state “SOa” and state “SOb” are defined as logic “high (H)” state and logic “low (L)” state, respectively.

In the meantime, as current information communication technology requires high integration and high speed, it is required to transmit more states, that is, more bits of data, using a limited number of transmission lines.

However, the transmission efficiency (the number of data bits/the number of transmission lines) of the conventional differential signal transmitting apparatus is ½. In other words, in the conventional differential signal transmitting apparatus, two states, that is, 1-bit data, can be transmitted using the two transmission lines.

Therefore, it is desired that a differential signal transmitting apparatus is improved to have higher transmission efficiency to comply with the current information communication technology requiring high integration and high speed.

### SUMMARY OF THE INVENTION

Accordingly, the present invention has been made keeping in mind the above problems occurring in the prior art, and an object of the present invention is to provide an apparatus and method for transmitting a differential signal, which has high transmission efficiency.

In order to accomplish the above object, the present invention provides a differential signal transmitting apparatus for transmitting data information from a signal transmitting unit to a signal receiving unit. The differential signal transmitting apparatus comprises first to third transmission lines to transmit the data information provided from the signal transmitting unit. The data information is recognized based on a sequence of voltage levels at ends of the first to third transmission lines located in the signal receiving unit.

According to an embodiment of the present invention, the differential signal transmitting apparatus may further comprise a first matching unit disposed between the ends of the first and second transmission lines located in the signal receiving unit; a second matching unit disposed between the ends of the second and third transmission lines located in the signal receiving unit; and a third matching unit disposed between the ends of the third and first transmission lines located in the signal receiving unit. Further, each of the first to third matching units may have an impedance matching with an impedance of each of the first to third transmission lines.

Further, in order to accomplish the above object, the present invention provides a differential signal transmitting method of transmitting data information from a signal transmitting unit to a signal receiving unit. The differential signal transmitting method comprises the steps of transmitting the data information through first to third transmission lines formed between the signal transmitting unit and the signal receiving unit by the signal transmitting unit; receiving the data information by the signal receiving unit; and recognizing the received data information by the signal receiving unit. The received data information is recognized based on a sequence of voltage levels at ends of the first to third transmission lines located in the signal receiving unit.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view showing a conventional differential signal transmitting apparatus;

FIGS. 2a and 2b are enlarged views each showing a part of a signal receiving unit of FIG. 1;

FIG. 3 is a view conceptually showing a differential signal transmitting apparatus according to an embodiment of the present invention;

FIGS. 4a to 4f are enlarged views each showing a part of a signal receiving unit of FIG. 3; and

FIG. 5 is a view showing data information transmission results by a differential signal transmitting method according to an embodiment of the present invention.

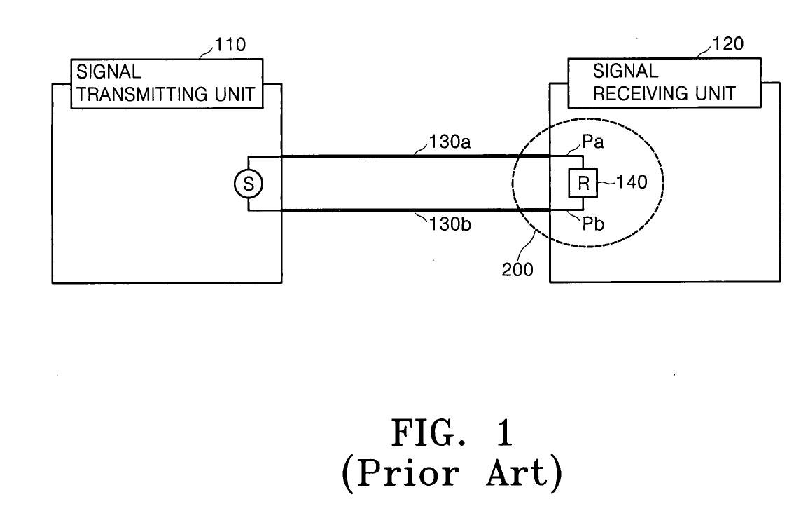

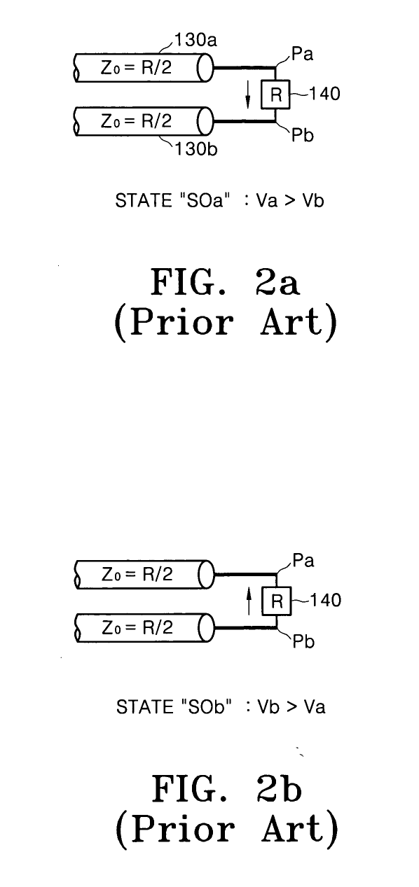

### DESCRIPTION OF THE PREFERRED EMBODIMENTS

Hereinafter, embodiments of the present invention will be described in detail with reference to the attached drawings.

Reference now should be made to the drawings, in which the same reference numerals are used throughout the different drawings to designate the same or similar components.

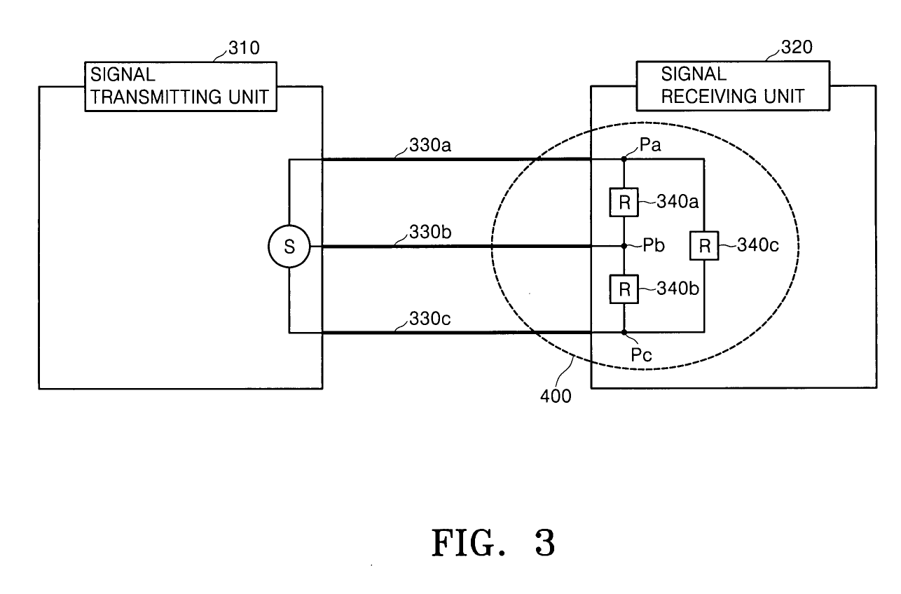

FIG. 3 is a view conceptually showing a differential signal transmitting apparatus according to an embodiment of the present invention. As shown in FIG. 3, the differential signal transmitting apparatus includes a signal transmitting unit 310, a signal receiving unit 320 and first to third transmission lines 330a, 330b and 330c to transmit data information from the signal transmitting unit 310 to the signal receiving unit 320. The signal receiving unit 320 receives signals generated by the signal transmitting unit 310 through ports Pa, Pb and Pc.

Further, in order to prevent the distortion of data information being transmitted, each of first to third matching units 340a, 340b and 340c is placed between the ends of any two of the first to third transmission lines 330a, 330b and 330c located in the signal receiving unit 320. The first matching unit 340a is disposed between the ends of the first and second transmission lines 330a and 330b, the second matching unit 340b is disposed between the ends of the second and third transmission lines 330b and 330c, and the third matching unit 340c is disposed between the ends of the third and first transmission lines 330c and 330a.

In the meantime, the data information received by the signal receiving unit 320 is recognized based on the voltage levels at the ends of the first to third transmission lines located in the signal receiving unit 320, that is, the ports Pa, Pb and Pc. The voltage levels are different from each other to have a sequence from the highest voltage level to the lowest voltage level. The sequence of the voltage levels at the ports Pa, Pb and Pc is recognized based on the direction of current flowing the first to third matching means 340a, 340b and 340c.

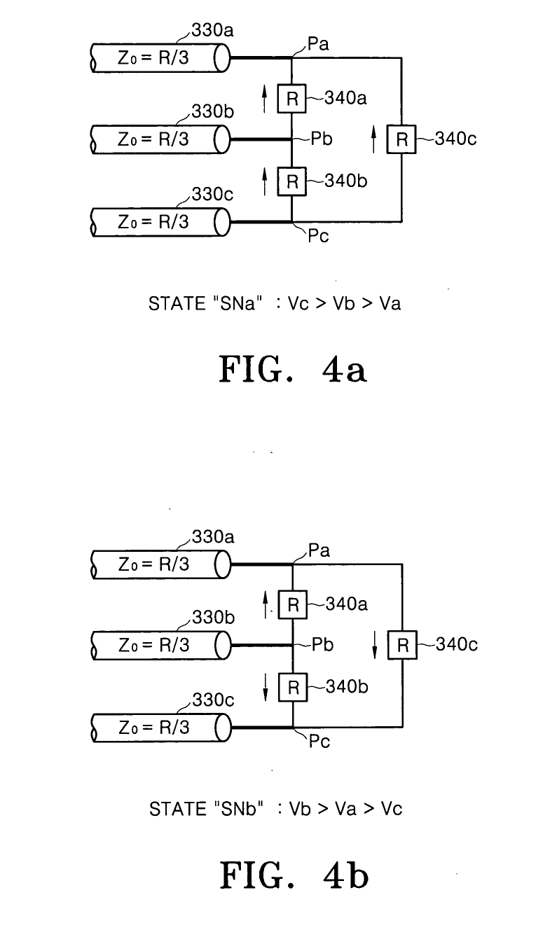

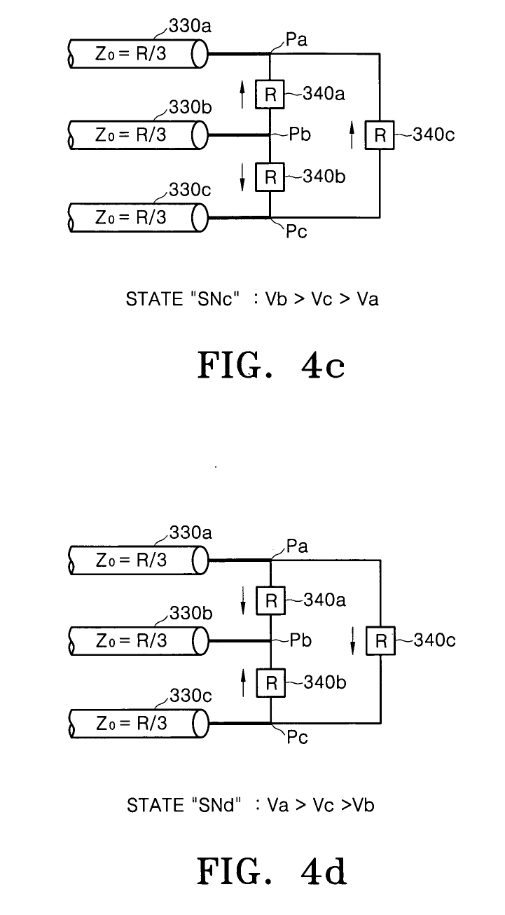

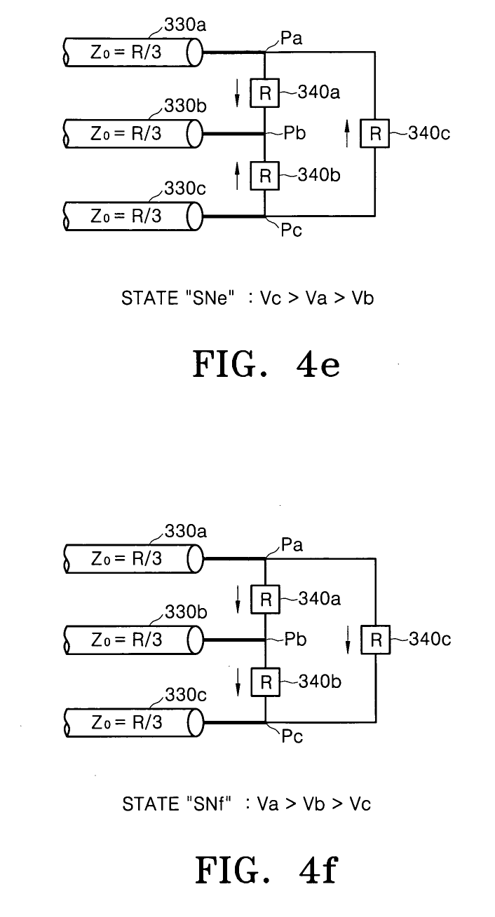

FIGS. 4a to 4f are views each showing a part 400 of the signal receiving unit 320 of FIG. 3, in which the impedance values of the transmission lines and the matching units are modeled and expressed. In accordance with the theoretical calculation, if the impedance value Z₀ of each of the transmission lines 330a, 330b and 330c is R/3, it is preferable that the impedance of each of the first to third matching units 340a to 340c 140 is R. In this case, the distortion of data information transmitted through the first to third transmission lines 330a, 330b and 330c is minimized.

Then, six states of data information transmitted at one frame through the differential signal transmitting apparatus of the present invention are described in detail with reference to FIGS. 4a to 4f.

Referring to FIG. 4a, the direction of a current flow is Pc→Pb→Pa. Therefore, the voltage levels at the respective ports Pa, Pb and Pc are Vc>Vb>Va. In the present specification, a state shown in FIG. 4a is designated as state “SNa”.

Referring to FIG. 4b, the direction of a current flow is Pb→Pa→Pc. Therefore, the voltage levels at the respective ports Pa, Pb and Pc are Vb>Va>Vc. In the present specification, a state shown in FIG. 4b is designated as state “SNb”.

Referring to FIG. 4c, the direction of a current flow is Pb→Pc→Pa. Therefore, the voltage levels at the respective ports Pa, Pb and Pc are Vb>Vc>Va. In the present specification, a state shown in FIG. 4c is designated as state “SNc”.

Referring to FIG. 4d, the direction of a current flow is Pa→Pc→Pb. Therefore, the voltage levels at the respective ports Pa, Pb and Pc are Va>Vc>Vb. In the present specification, a state shown in FIG. 4d is designated as state “SNd”.

Referring to FIG. 4e, the direction of a current flow is Pc→Pa→Pb. Therefore, the voltage levels at the respective ports Pa, Pb and Pc are Vc>Va>Vb. In the present specification, a state shown in FIG. 4e is designated as state “SNe”.

Referring to FIG. 4f, the direction of a current flow is Pa→Pb→Pc. Therefore, the voltage levels at the respective ports Pa, Pb and Pc are Va>Vb>Vc. In the present specification, a state shown in FIG. 4f is designated as state “SNf”.

Consequently, the differential signal transmitting apparatus and method of the present invention transmits six states “SNa to SNf”, that is, 2.58(=log₂₆)-bit data, at one frame using the three transmission lines. Therefore, according to the differential signal transmitting apparatus and method of the present invention, transmission efficiency is 2.58/3, and is remarkably improved compared to the prior art.

In the meantime, the differential signal transmitting method of transmitting data information according to the present invention can be easily extended.

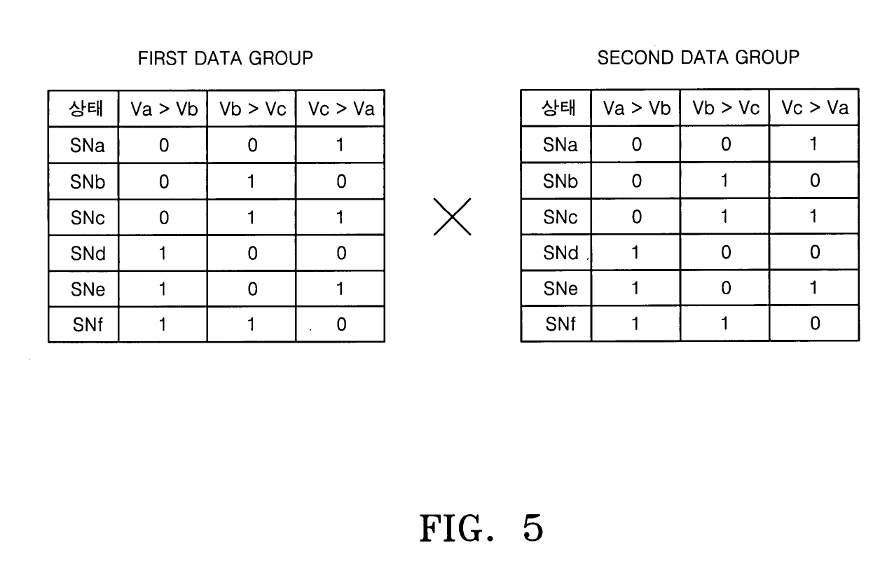

FIG. 5 is a view showing data information transmission results by a differential signal transmitting method according to another embodiment of the present invention, in which the results transmitted by the differential signal transmitting method using two frames are depicted. First, each of first and second data groups is transmitted at one frame. At this time, the method of transmitting each of the first and second data groups is performed as described above in the embodiment of FIG. 3 and FIGS. 4a to 4f. Further, the recognition of the information of the first and second data groups is performed based on the sequence of the voltage levels at the ends of the first to third transmission lines 330a to 330c located in the signal receiving unit 320.

In the embodiment of FIG. 5, the first and second data groups are sequentially transmitted, and data information is recognized by the combination of the first and second data groups.

Therefore, according to the method of transmitting data information using two frames by the differential signal transmitting apparatus of the present invention, data information with 36 states (=6×6) can be transmitted. The method has transmission efficiency enabling 5.xx (log₂36) bits to be transmitted at two frames. Such transmission efficiency is remarkably higher than that of the prior art enabling two bits, that is, four states, to be transmitted at two frames.

Although the preferred embodiments of the present invention have been disclosed for illustrative purpose, those skilled in the art will appreciate that various modifications, additions and substitutions are possible, without departing from the scope and spirit of the invention as disclosed in the accompanying claims. For example, in the embodiments of the present specification, when the two data groups are transmitted at two frames, the first and second data groups are transmitted in series through the first to third transmission lines. However, it is apparent to those skilled in the art that the first and second data groups are transmitted in parallel at two frames. That is, the first data group is transmitted through first to third transmission lines and the second data group is transmitted through fourth to sixth transmission lines, the information of the first data group and the information of the second data group are recognized, respectively, and entire data information transmitted from the signal transmitting unit to the signal receiving unit is recognized by a combination of the recognized information of the first and second data groups. Therefore, the technical scope of protection of the present invention must be defined by the technical spirit of the accompanying claims.

As described above, the present invention provides an apparatus and method for transmitting a differential signal through a ternary transmission line, which can transmit data information with six states, that is, 2.58-bit data, at one frame using three transmission lines. Therefore, the present invention is advantageous in that it can remarkably improve the transmission efficiency (the number of data bits/the number of transmission lines) of the differential signal transmitting apparatus.

What is claimed is:

1. A differential signal transmitting apparatus for transmitting data information provided from a signal transmitting unit to a signal receiving unit, comprising:
transmission lines to transmit the data information provided from the signal transmitting unit,
wherein the data information is recognized in association with voltage levels at ends of the transmission lines located in the signal receiving unit, and the number of the transmission lines is at least three.

2. The differential signal transmitting apparatus according to claim 1, further comprising:
first matching unit disposed between ends of first and second transmission lines located in the signal receiving unit;
second matching unit disposed between ends of the second and third transmission lines located in the signal receiving unit; and
third matching unit disposed between the ends of the third and first transmission lines located in the signal receiving unit;
wherein each of the first to third matching units has an impedance matching with an impedance of the first to third transmission lines to prevent distortion of the data information.

3. The differential signal transmitting apparatus according to claim 2, wherein the first to third matching units have a substantially same impedance.

4. The differential signal transmitting apparatus according to claim 3, wherein each of the first to third matching units has the impedance about three times the impedance of each of the first to third transmission lines.

5. The differential signal transmitting apparatus according to claim 2, wherein the ends of the first to third transmission lines have first to third voltage levels, respectively, which are different from each other, the date information being recognized based on a sequence of the first to third voltage levels.

6. A differential signal transmitting method of transmitting data information from a signal transmitting unit to a signal receiving unit, comprising:
transmitting the data information through at least three transmission lines disposed between the signal transmitting unit and the signal receiving unit;
receiving the data information by the signal receiving unit; and
recognizing the received data information based on a sequence of voltage levels at ends of the first to third transmission lines located in the signal receiving unit.

7. The differential signal transmitting method further comprising:
providing a first matching unit between the ends of the first and second transmission lines located in the signal receiving unit;
providing a second matching unit between the ends of the second and third transmission lines located in the signal receiving unit; and
providing a third matching unit between the ends of the third and first transmission lines located in the signal receiving unit.

8. The differential signal transmitting method according to claim 7, wherein the recognizing the received data information includes determining the sequence of the voltage levels at the ends of the first to third transmission lines based on the direction of the current.

9. The differential signal transmitting method according to claim 7, wherein each of the first to third matching means has an impedance three times an impedance of each of the first to third transmission lines.

10. A differential signal transmitting method of transmitting data information from a signal transmitting unit to a signal receiving unit, comprising:
transmitting a first data group through first to third transmission lines formed between the signal transmitting unit and the signal receiving unit receiving the first data group by the signal receiving unit;
recognizing the first data group by the signal receiving unit;
transmitting a second data group through the first to third transmission lines by the signal transmitting unit;
receiving the second data group by the signal receiving unit;
recognizing the second data group by the signal receiving unit; and
recognizing the data information using a combination of the first and second data groups;
wherein the first and second data groups are recognized based on a sequence of voltage levels at ends of the first to third transmission lines located in the signal receiving unit.
